(19) United States
(12) Patent Application Publication
(10) Pub. No.: US 2010/0012183 A1
(43) Pub. Date: Jan. 21, 2010

(54) Thin Film Solar Cell Having Photo-Luminescent Medium Coated Therein And Method For Fabricating The Same

(76) Inventor: Chih-Hung Yeh, Miaoli (TW)

Correspondence Address: LIN & ASSOCIATES INTELLECTUAL PROPERTY, INC., P.O. BOX 2339, SARATOGA, CA, 95070-0339, US

(21) Appl. No.: 12/503,073

(22) Filed: Jul. 15, 2009

(30) Foreign Application Priority Data
Jul. 17, 2008 (TW) 097127056

(51) Int. Cl. H01L 31/00; B05D 5/12

(52) U.S. Cl. 136/256; 427/74

(57) ABSTRACT

A thin film solar cell having a photo-luminescent medium coated therein and a method for fabricating the same are provided. The thin film solar cell at least includes a transparent layer, a front electrode layer, a photoconductive layer, and a back electrode layer, which are sequentially stacked in that order from a light incident surface of the thin film solar cell. The transparent layer is a cover glass or a transparent substrate. The thin film solar cell further includes a photo-luminescent medium disposed on outer surface or inner surface of the transparent layer for absorbing the rest short wavelength light contained in the incident light and is then excited to emit a long wavelength light which can be effectively absorbed by the photoconductive layer. In such a way, the spectrum of the incident light is shifted, and thus an improved energy conversion efficiency is achieved.

### BACKGROUND OF THE INVENTION

1. Field of the Invention

The present invention relates generally to a thin film solar cell and a method for fabricating the same, and more particularly, to a thin film solar cell having a photo-luminescent medium coated therein and a method for fabricating the same.

2. The Prior Arts

Typically, for the purpose of improving the photoelectric conversion efficiency of a solar cell, a thin film of fluorescent substance is often coated on a glass substrate at a light receiving face of the solar cell. For example, JP Publication No. 2001-7377 (JP Application No. 11-215711) discloses a solar cell module 100. As shown in FIG. 1A, the solar cell module 100 includes a fluorescent coloring agent layer 101, a soda glass layer 102, an EVA filler layer 103, a solar cell 104 having an n+pp+polysilicon structure, and a back electrode sheet 105 sequentially stacked one on another from top to bottom. When absorbing a short wavelength light (<400 nm), the fluorescent color agent layer 101 can be excited to emit a long wavelength light. In such a way, the solar cell module 100 is supposed to achieve an improved energy conversion efficiency. Similarly, JP Publication No. 11-220147 (JP Application No. 10-18909) discloses an amorphous silicon solar cell 110 employing a fluorescent film for achieving an improved energy conversion efficiency. As shown in FIG. 1B, the amorphous silicon solar cell 110 includes a fluorescent film 111, a transparent substrate 112, a front electrode 113, a photoconductive layer 114, and a back electrode 115 sequentially stacked one on another from bottom to top. The light is incident from a light incident surface of the fluorescent film 111 disposed at the bottom of the amorphous silicon solar cell 110. The fluorescent film 111 is coated on an outer surface of the transparent substrate 112 by depositing with polymer binders. Such a fluorescent film 111 can also absorb a short wavelength light, and then be excited to emit a long wavelength light. As such, a larger range of spectrum of the incident light can be absorbed by the amorphous silicon solar cell 110. In such a way, the energy conversion efficiency of the solar cell can also be improved.

Further, JP Publication No. 2001-111091 (JP Application No. 11-321552) and JP Publication No. 2001-94129 (JP Application No. 11-270812) propose a thin film solar cell having a fluorescent medium. Such a thin film solar cell is specifically featured with a Cd—Te (cadmium-tellurium) structure. The fluorescent medium is disposed on a light incident surface of a transparent substrate. When absorbing a short wavelength light, the fluorescent medium can be excited to emit a long wavelength light. Accordingly, the spectrum of the incident light is shifted, and thus an improved energy conversion efficiency is achieved.

However, none of the selection and the coating processes of the fluorescent media employed by the aforementioned conventional solar cells has been optimized in accordance with the optimal light absorbing region of the photoconductive layer of the solar cell, as well as the characteristics of the substrate, the front electrode, and the window layer. Further, the fluorescent media employed in the conventional technologies are mainly organic dyes, and therefore the stabilities thereof are usually insufficient. As to the photoconductive layer, the conventional technologies only provide solutions with respect to crystalline silicon materials and CdTe structure for improving the energy conversion efficiency. However, there is no solution provided with respect to the copper indium selenide (CIS) or copper indium gallium selenide (CIGS) thin film solar cell for improving the energy conversion efficiency. It is well known that comparing with the CdTe structure thin film solar cell, the CIS or CIGS thin film solar cell usually has a superior photoelectric conversion efficiency. As such, a solution specifically with respect to the CIS or CIGS thin film solar cell for achieving a better photoelectric conversion efficiency is very much desired.

### SUMMARY OF THE INVENTION

A primary objective of the present invention is to provide a thin film solar cell having a photo-luminescent medium coated therein. When receiving the incident light, the photo-luminescent medium can be excited, and thus improving a spectrum sensibility of a photoconductive layer, and achieving an improved photoelectric conversion efficiency.

A further objective of the present invention is to provide a thin film solar cell having a photo-luminescent medium coated therein. The thin film solar cell is a substrate-type solar cell, in which the photo-luminescent medium is coated at an outer surface of a cover glass of the solar cell for improving a spectrum sensibility of a photoconductive layer.

Another objective of the present invention is to provide a thin film solar cell having a photo-luminescent medium coated therein. The thin film solar cell is a superstrate-type solar cell, in which the photo-luminescent medium is coated at an outer surface of a substrate of the solar cell for improving a spectrum sensibility of a photoconductive layer.

A furthermore objective of the present invention is to provide a thin film solar cell having a photo-luminescent medium coated therein. The thin film solar cell is a substrate-type solar cell, in which the photo-luminescent medium is coated at an inner surface of a cover glass of the solar cell for converting a visible light having a shorter wavelength into a visible light having a longer wavelength, thus improving a spectrum sensibility of a photoconductive layer.

A still further objective of the present invention is to provide a thin film solar cell having a photo-luminescent medium coated therein. The thin film solar cell is a superstrate-type solar cell, in which the photo-luminescent medium is coated at an inner surface of a substrate of the solar cell, for converting a visible light having a shorter wavelength into a visible light having a longer wavelength, thus improving a spectrum sensibility of a photoconductive layer.

For achieving the foregoing objectives and others, the present invention provides a thin film solar cell having a photo-luminescent medium coated therein and a method for fabricating the same. The thin film solar cell at least includes a front electrode layer, a photoconductive layer, a back electrode layer, and a substrate, which are sequentially stacked in that order from a light incident surface of the thin film solar cell. The thin film solar cell further includes a photo-luminescent medium disposed adjacent to the front electrode layer, at the light incident surface, for receiving the incident light and being excited thereby. In such a way, the spectrum of the incident light is shifted, and thus an improved energy conversion efficiency is achieved.

### BRIEF DESCRIPTION OF THE DRAWINGS

The present invention will be apparent to those skilled in the art by reading the following detailed description of a preferred embodiment thereof, with reference to the attached drawings, in which:

FIG. 1A is a schematic diagram illustrating a conventional solar cell having fluorescent media coated thereon;

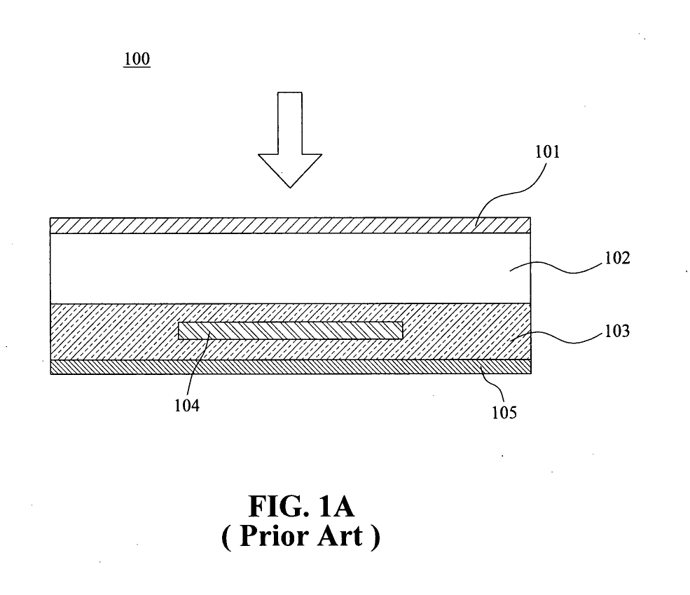

FIG. 1B is a schematic diagram illustrating another conventional solar cell having fluorescent media coated thereon;

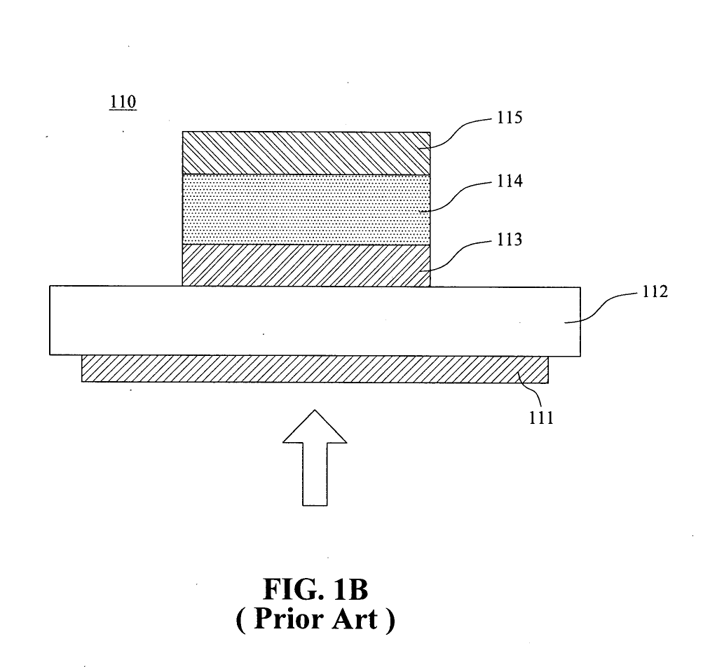

FIG. 2A is a cross-sectional view of a substrate-type solar cell having a photo-luminescent medium coated therein, according to a first embodiment of the present invention;

FIG. 2B is a cross-sectional view of a substrate-type solar cell having a photo-luminescent medium coated therein, according to a second embodiment of the present invention;

FIG. 3A is a cross-sectional view of a superstrate-type solar cell having a photo-luminescent medium coated therein, according to a third embodiment of the present invention;

FIG. 3B is a cross-sectional view of a superstrate-type solar cell having a photo-luminescent medium coated therein, according to a fourth embodiment of the present invention; and

FIG. 4 is a flow chart illustrating method for fabricating a thin film solar cell having a photo-luminescent medium coated therein according to a fifth embodiment of the present invention.

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

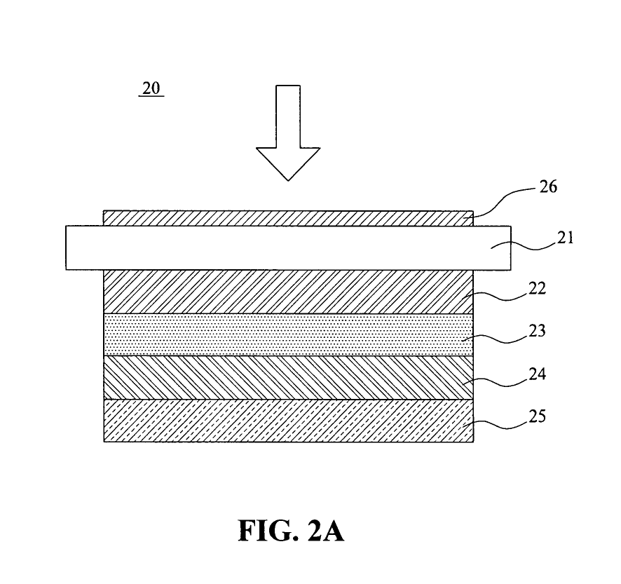

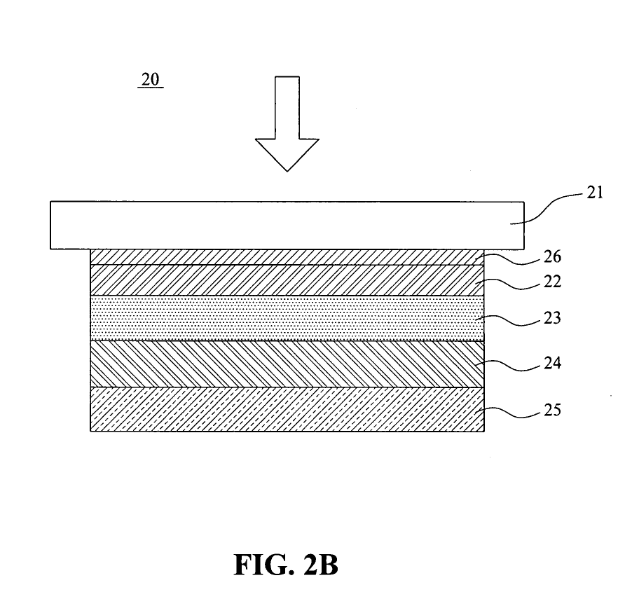

FIG. 2A is a cross-sectional view of a substrate-type solar cell having a photo-luminescent medium coated therein, according to a first embodiment of the present invention. As shown in FIG. 2A, the thin film solar cell 20 is substrate-type. The thin film solar cell 20 includes a transparent layer 21, a front electrode layer 22, a photoconductive layer 23, a back electrode layer 24, and a substrate 25, all of which are sequentially stacked in that order from a light incident surface of the thin film solar cell 20. The transparent layer 21 is a cover glass. The transparent layer 21 has an inner surface and an outer surface. The inner surface of the transparent layer 21 is in contact with the front electrode layer 22, and the outer surface of the transparent layer 21 is positioned opposite to the inner surface of the transparent layer 21. According to an aspect of the first embodiment of the present invention, the thin film solar cell 20 further includes a photo-luminescent medium 26 coated on the outer surface of the transparent layer 21. The photo-luminescent medium 26 preferably contains an adhesive therein for assuring that the photo-luminescent medium 26 is solidly attached to the outer surface of the transparent layer 21. When the solar light enters the thin film solar cell 20 from the light incident surface, the solar light hits the photo-luminescent medium 26 at first. Therefore, the photo-luminescent medium 26 absorbs a part of the incident solar light having a short wavelength and is then excited to emit a long wavelength light. Please note, the short wavelength light and the long wavelength light recited hereby are relative definitions. For example, an ultraviolet (UV) light is taken as a short wavelength light hereby. The UV light is absorbed by the photo-luminescent medium 26 and thus excites the photo-luminescent medium 26 to emit a light spectrum which can be effectively absorbed by the photoconductive layer 23, e.g., blue, green, orange, or red light, each of which is a long wavelength light relative to the UV light. In such a way, the higher spectra response (HSR) region of the photoconductive layer 23 is improved, thus achieving an improved photoelectric conversion efficiency.

According to an aspect of the first embodiment of the present invention, the photo-luminescent medium 26 is selected from the group consisting of SR₅(PO₃)₃Cl:Eu, and BaMgAl₁₀O₁₇:Eu, for converting the UV light into a blue light. According to another aspect of the first embodiment of the present invention, the photo-luminescent medium 26 is selected from the group consisting of BaMgAl₁₀O₁₇:Eu, and (Ce,Tb)MgAl₁₁O₁₉:Eu, for converting the UV light into a green light. According to a further aspect of the first embodiment of the present invention, the photo-luminescent medium 26 is Mg₄CeO_{5.5}:Mn for converting the UV light into an orange light. According to still another aspect of the first embodiment of the present invention, the photo-luminescent medium 26 is Y₂O₂S:Eu, for converting the UV light into a red light. Furthermore, the photo-luminescent medium 26 can also be an inorganic compound containing a host and an activator. The host is selected from the group consisting of metal oxide, sulfide, nitride, and oxynitride, while the activator is selected from the group consisting of cerium (Ce), terbium (Tb), europium (Eu), manganese (Mn), and praseodymium (Pr). Specifically, the inorganic compound has an optimal external quantum efficiency (EQE) approximate to 90%. When such the inorganic compound is excited, a light in the HSR region of the photoconductive layer 23 is emitted therefrom, for achieving a better photoelectric conversion efficiency.

FIG. 2B is a cross-sectional view of a substrate-type solar cell having a photo-luminescent medium coated therein, according to a second embodiment of the present invention. Referring to FIG. 2B, the thin film solar cell 20 is substrate-type. The thin film solar cell 20 includes a transparent layer 21, a front electrode layer 22, a photoconductive layer 23, a back electrode layer 24, and a substrate 25, all of which are sequentially stacked in that order from a light incident surface of the thin film solar cell 20. The transparent layer 21 is a cover glass. The transparent layer 21 has an inner surface and an outer surface. The inner surface of the transparent layer 21 is adjacent to the front electrode layer 22, while the outer surface of the transparent layer 21 is positioned apart from the front electrode layer 22. According to an aspect of the second embodiment of the present invention, the thin film solar cell 20 further includes a photo-luminescent medium 26 coated on the inner surface of the transparent layer 21. Alternatively, according to another aspect of the second embodiment, the photo-luminescent medium 26 is coated on a surface of the front electrode layer 22 adjacent to the inner surface of the transparent layer 21. The photo-luminescent medium 26 preferably contains an adhesive therein. When the solar light enters the thin film solar cell 20 from the light incident surface, the UV light contained in the solar light will filtered by the transparent layer 21 at first. Therefore, the photo-luminescent medium 26 absorbs the rest short wavelength light contained in the solar light and is then excited to emit a long wavelength light which can be effectively absorbed by the photoconductive layer 23. In such a way, the higher spectra response (HSR) region of the photoconductive layer 23 is improved, thus achieving an improved photoelectric conversion efficiency.

According to an aspect of the second embodiment of the present invention, the photo-luminescent medium 26 is (Ba,Sr)₂SiO₄:Eu for converting a blue light into a green light. According to another aspect of the second embodiment of the present invention, the photo-luminescent medium 26 is selected from the group consisting of Y₃Al₅O₁₂:Ce, (Ba,Sr)₂SiO₄:Eu and Li-α-SiAlON:Eu, for converting a blue or a green light into a yellow light. According to a further aspect of the second embodiment of the present invention, the photo-luminescent medium 26 is selected from the group consisting of Ca-α-SiAlON:Eu and (Sr,Ca)AlSiN₃:Eu for converting a blue light or a green light into an orange light. According to still another aspect of the second embodiment of the present invention, the photo-luminescent medium 26 is selected from the group consisting of CaS:Eu, SrS:Eu, and CaAlSiN₃:Eu for converting a blue light or a green light into a red light. Furthermore, the photo-luminescent medium 26 can also be an inorganic compound containing a host and an activator. The host is selected from the group consisting of metal oxide, sulfide, nitride, and oxynitride, while the activator is selected from the group consisting of cerium (Ce), terbium (Tb), europium (Eu), manganese (Mn), and praseodymium (Pr). Specifically, the inorganic compound has an optimal external quantum efficiency (EQE) approximate to 90%. When such the inorganic compound is excited, a light in the HSR region of the photoconductive layer 23 is emitted therefrom, for achieving a better photoelectric conversion efficiency.

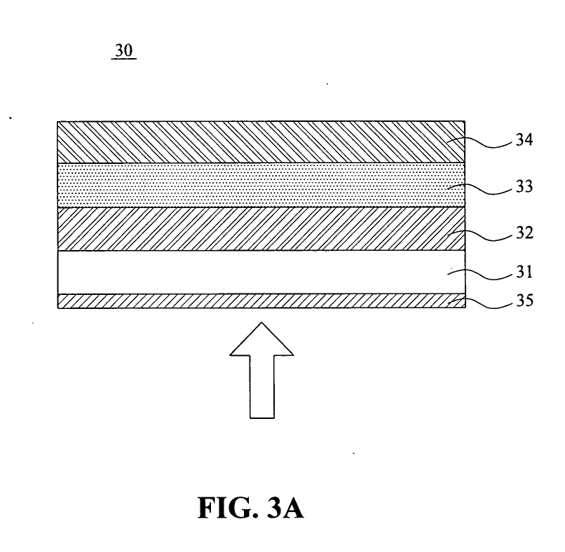

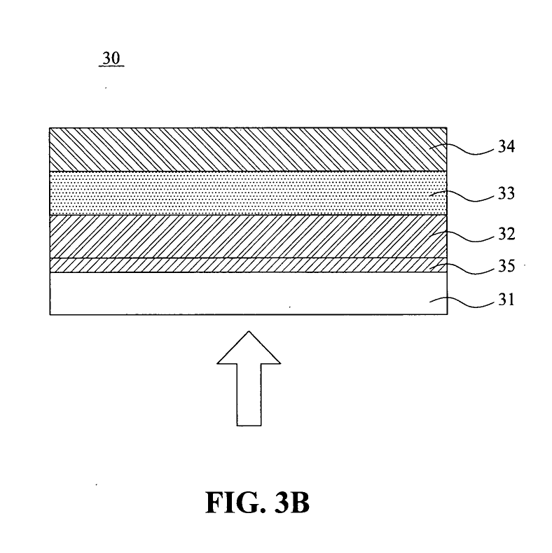

FIG. 3A is a cross-sectional view of a superstrate-type solar cell having a photo-luminescent medium coated therein, according to a third embodiment of the present invention. Referring to FIG. 3A, the thin film solar cell 30 is a superstrate-type solar cell. The thin film solar cell 30 includes a transparent layer 31, a front electrode layer 32, a photoconductive layer 33, and a back electrode layer 34, all of which are sequentially stacked in that order from a light incident surface of the thin film solar cell 30. The transparent layer 31 is a transparent substrate. The transparent layer 31 has an inner surface and an outer surface. The inner surface of the transparent layer 31 is adjacent to the front electrode layer 32, while the outer surface of the transparent layer 31 is positioned apart from the front electrode layer 32. According to an aspect of the third embodiment of the present invention, the thin film solar cell 30 further includes a photo-luminescent medium 35 coated on the outer surface of the transparent layer 31. The photo-luminescent medium 35 preferably contains an adhesive therein. When the solar light enters the thin film solar cell 30 from the light incident surface, the solar light hits the photo-luminescent medium 35 at first. Therefore, the UV light is absorbed by the photo-luminescent medium 35 and thus excites the photo-luminescent medium 35 to emit a light spectrum which can be effectively absorbed by the photoconductive layer 33, e.g., blue, green, orange, or red light, each of which is a long wavelength light relative to the UV light. In such a way, the higher spectra response (HSR) region of the photoconductive layer 33 is improved, thus achieving an improved photoelectric conversion efficiency.

According to an aspect of the third embodiment of the present invention, the photo-luminescent medium 35 is selected from the group consisting of SR₅(PO₃)₃Cl:Eu and BaMgAl₁₀O₁₇:Eu, for converting the UV light into a blue light. According to another aspect of the third embodiment of the present invention, the photo-luminescent medium 35 is selected from the group consisting of BaMgAl₁₀O₁₇:Eu and (Ce,Tb)MgAl₁₁O₁₉:Eu, for converting the UV light into a green light. According to a further aspect of the third embodiment of the present invention, the photo-luminescent medium 35 is Mg₄CeO_{5.5}:Mn for converting the UV light into an orange light. According to still another aspect of the third embodiment of the present invention, the photo-luminescent medium 35 is of Y₂O₂S:Eu, for converting the UV light into a red light. Furthermore, the photo-luminescent medium 35 can also be an inorganic compound containing a host and an activator. The host is selected from the group consisting of metal oxide, sulfide, nitride, and oxynitride, while the activator is selected from the group consisting of cerium (Ce), terbium (Tb), europium (Eu), manganese (Mn), and praseodymium (Pr). Specifically, the inorganic compound has an optimal external quantum efficiency (EQE) approximate to 90%. When such the inorganic compound is excited, a light in the HSR region of the photoconductive layer 33 is emitted therefrom, for achieving a better photoelectric conversion efficiency.

FIG. 3B is a cross-sectional view of a superstrate-type solar cell having a photo-luminescent medium coated therein, according to a fourth embodiment of the present invention. Referring to FIG. 3B, the thin film solar cell 30 is a superstrate-type solar cell. The thin film solar cell 30 includes a transparent layer 31, a front electrode layer 32, a photoconductive layer 33, and a back electrode layer 34, all of which are sequentially stacked in that order from a light incident surface of the thin film solar cell 30. The transparent layer 31 is a transparent substrate. The transparent layer 31 has an inner surface and an outer surface. The inner surface of the transparent layer 31 is adjacent to the front electrode layer 32, while the outer surface of the transparent layer 31 is positioned apart from the front electrode layer 32. According to an aspect of the third embodiment of the present invention, the thin film solar cell 30 further includes a photo-luminescent medium 35 coated on the inner surface of the transparent layer 31. The photo-luminescent medium 35 preferably contains an adhesive therein. When the solar light enters the thin film solar cell 30 from the light incident surface, the solar light passes through the transparent layer 31 at first, in which the UV light contained therein is filtered out. Therefore, the photo-luminescent medium 35 absorbs the rest short wavelength light contained in the solar light and is then excited to emit a long wavelength light which can be effectively absorbed by the photoconductive layer 33. In such a way, the higher spectra response (HSR) region of the photoconductive layer 33 is improved, thus achieving an improved photoelectric conversion efficiency.

According to an aspect of the fourth embodiment of the present invention, the photo-luminescent medium 35 is (Ba,Sr)₂SiO₄:Eu for converting a blue light into a green light. According to another aspect of the fourth embodiment of the present invention, the photo-luminescent medium 35 is selected from the group consisting of Y₃Al₅O₁₂:Ce, (Ba,Sr)₂SiO₄:Eu and Li-α-SiAlON:Eu, for converting a blue or a green light into a yellow light. According to a further aspect of the fourth embodiment of the present invention, the photo-luminescent medium 35 is selected from the group consisting of Ca-α-SiAlON:Eu and (Sr, Ca)AlSiN₃:Eu for converting a blue light or a green light into an orange light. According to still another aspect of the fourth embodiment of the present invention, the photo-luminescent medium 35 is selected from the group consisting of CaS:Eu, SrS:Eu, and CaAlSiN₃:Eu for converting a blue light or a green light into a red light. Furthermore, the photo-luminescent medium 35 can also be an inorganic compound containing a host and an activator. The host is selected from the group consisting of metal oxide, sulfide, nitride, and oxynitride, while the activator is selected from the group consisting of cerium (Ce), terbium (Tb), europium (Eu), manganese (Mn), and praseodymium (Pr). Specifically, the inorganic compound has an optimal external quantum efficiency (EQE) approximate to 90%. When such the inorganic compound is excited, a light in the HSR region of the photoconductive layer 33 is emitted therefrom, for achieving a better photoelectric conversion efficiency.

In the first embodiment and the second embodiment of the present invention, the substrate 25 can be made of a transparent glass, a thermally stable polymer material, or a metal material. The photoconductive layer 23 can be a CIGS layer or a CIS layer. Preferably, the photoconductive layer 23 can be further grown with a cadmium sulfide (CdS) layer thereon, thus obtaining a photoconductive layer having a p-n type composite structure (i.e., CIGS/CdS or CIGS/CdS). The back electrode layer 24 is made of molybdenum (Mo). The front electrode layer 22 is made of a transparent conductive oxide, which can be selected from the group consisting of tin oxide (SnO₂), indium tin oxide (ITO), zinc oxide (ZnO), aluminum zinc oxide (AZO), gallium zinc oxide (GZO), and indium zinc oxide (IZO).

In the third embodiment and the fourth embodiment of the present invention, the transparent layer 31 is a transparent substrate made of soda lime glass (SLG), low iron white glass, or alkali-free glass. When the photoconductive layer 33 is made of amorphous silicon (a-Si), polysilicon, or microcrystalline silicon, the photoconductive layer 33 achieves a p-i-n type composite structure (not shown in the drawings), while the back electrode layer 34 can be made of a metal selected from the group consisting of silver (Ag), aluminum (Al), chromium (Cr), titanium (Ti), nickel (Ni), and gold (Au). When the photoconductive layer 33 is made of CIS or CIGS, the photoconductive layer 23 is preferably further grown with a cadmium sulfide (CdS) layer thereon, thus obtaining a photoconductive layer having a p-n type composite structure (i.e., CIGS/CdS or CIGS/CdS) (not shown in the drawings), while the back electrode layer 34 is made of molybdenum (Mo). No matter the photoconductive layer 33 is the former or the latter, the front electrode layer 32 is made of a transparent conductive oxide, which can be selected from the group consisting of tin oxide (SnO₂), indium tin oxide (ITO), zinc oxide (ZnO), aluminum zinc oxide (AZO), gallium zinc oxide (GZO), and indium zinc oxide (IZO).

In any of the foregoing embodiments, the front electrode layer can be formed by a sputtering process, an atmospheric pressure chemical vapor deposition (APCVD) process, or a low pressure chemical vapor deposition (LPCVD) process. The front electrode layer can be formed to have a single layer structure or a multilayer structure. The back electrode layer can be formed to have a single layer structure or a multilayer structure. The back electrode layer can be formed by a sputtering process or a physical vapor deposition (PVD) process. When the photoconductive layer is composed of CIS or CIGS, the photoconductive layer is formed by a PVD process, including a sputtering process, or an evaporation process. When the photoconductive layer is composed of a-Si, polysilicon, or microcrystalline silicon, the photoconductive layer is formed by a plasma enhanced chemical vapor deposition (PECVD) process.

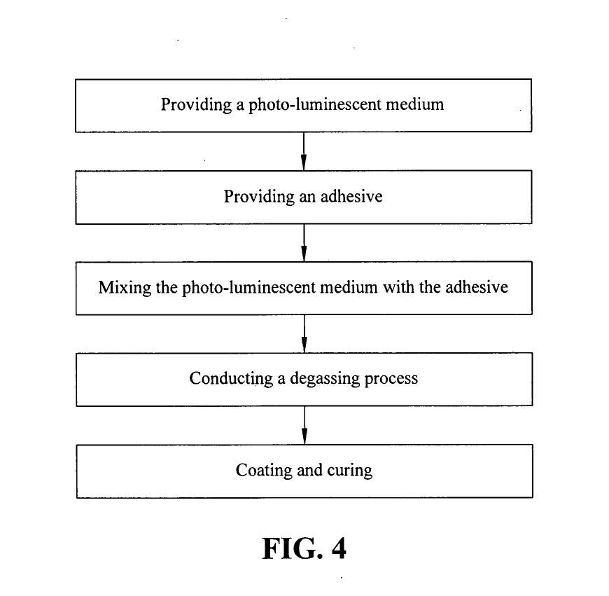

FIG. 4 is a flow chart illustrating method for fabricating a thin film solar cell having a photo-luminescent medium coated therein according to a fifth embodiment of the present invention. Referring to FIG. 4, according to the fifth embodiment, the present invention further provides a method for fabricating a thin film solar cell having a photo-luminescent medium coated therein. The method includes the following steps:

(1) providing a photo-luminescent medium, which can be either a single component or a mixture;

(2) providing an adhesive, which can be silica gel, silicone, epoxy, or ethylene vinyl acetate (EVA);

(3) mixing the photo-luminescent medium with the adhesive, so as to uniformly disperse a matrix of the photo-luminescent medium into the adhesive, for obtaining a mixture of the photo-luminescent medium and the adhesive, in which a content percentage of the photo-luminescent medium in the mixture ranges from 0.005% to 20%, and preferably from 0.05% to 1%;

(4) conducting a degassing process to the mixture of the photo-luminescent medium and the adhesive; and

(5) loading the degassed mixture into a coater for coating a photo-luminescent medium layer onto the thin film solar cell, and then curing the coated photo-luminescent medium, in which a method of coating the photo-luminescent medium layer onto the thin film solar cell can be selected from screen printing, roll coating, slit coating, gravure printing, and a slot die coating, and a thickness of the photo-luminescent medium coated on the thin film solar cell ranges from 10 μm to 200 μm, and preferably from 50 μm to 100 μm.

In the foregoing method, the materials, structures, and coating position of the photo-luminescent medium, the substrate, the front electrode layer, the photoconductive layer, and the back electrode layer are similar and can be learnt by referring to the discussion of the first embodiment through the fourth embodiment, and are not to be iterated hereby. Further, the photo-luminescent medium can be presented in any manner of fluorescent powder, fluorescent film, fluorescent agents, or fluorescent plate.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A thin film solar cell having a photo-luminescent medium coated therein, comprising:
a photo-luminescent medium, provided at a light incident surface of the thin film solar cell;
a transparent layer, stacked on the photo-luminescent medium layer;
a front electrode layer, stacked on the transparent layer;
a photoconductive layer, stacked on the front electrode layer; and
a back electrode layer, stacked on the photoconductive layer,
wherein the photo-luminescent medium layer is adapted for absorbing a part of an incident light having a relative short wavelength and then being excited to emit a light having a relative long wavelength, thus improving a higher spectra response (HSR) region of the photoconductive layer, and achieving an improved photoelectric conversion efficiency.

2. The thin film solar cell according to claim 1, wherein the photo-luminescent medium is selected from the group consisting of SR₅(PO₃)₃Cl:Eu, and BaMgAl₁₀O₁₇:Eu for converting a UV light into a blue light.

3. The thin film solar cell according to claim 1, wherein the photo-luminescent medium is selected from the group consisting of BaMgAl₁₀O₁₇:Eu, and (Ce,Tb)MgAl₁₁O₁₇:Eu for converting a UV light into a green light.

4. The thin film solar cell according to claim 1, wherein the photo-luminescent medium is Mg₄CeO_{5.5}:Mn for converting a UV light into an orange light.

5. The thin film solar cell according to claim 1, wherein the photo-luminescent medium is Y₂O₂S:Eu for converting a UV light into a red light.

6. The thin film solar cell according to claim 1, wherein the photo-luminescent medium is an inorganic compound comprising a host and an activator.

7. The thin film solar cell according to claim 6, wherein the host is selected from the group consisting of metal oxide, sulfide, nitride, and oxynitride.

8. The thin film solar cell according to claim 6, wherein the activator is selected from the group consisting of cerium (Ce), terbium (Tb), europium (Eu), manganese (Mn), and praseodymium (Pr).

9. The thin film solar cell according to claim 1, wherein a substrate further stacked under the back electrode layer.

10. The thin film solar cell according to claim 9, wherein the transparent layer is a cover glass.

11. The thin film solar cell according to claim 9, wherein the substrate is made of a transparent glass, a thermally stable polymer material, or a metal material.

12. The thin film solar cell according to claim 9, wherein the photoconductive layer is made of a material selected from the group consisting of copper indium selenide (CIS), and copper indium gallium selenide (CIGS).

13. The thin film solar cell according to claim 12, wherein the photoconductive layer is further grown with a cadmium sulfide (CdS) layer thereon, thus obtaining a photoconductive layer having a p-n type CIGS/CdS or CIGS/CdS composite structure.

14. The thin film solar cell according to claim 12, wherein the back electrode layer is made of molybdenum (Mo).

15. The thin film solar cell according to claim 12, wherein the photoconductive layer is formed by a physical vapor deposition (PVD) process, a sputtering process or an evaporation process.

16. The thin film solar cell according to claim 1, wherein the transparent layer is a transparent substrate made of a material selected from the group consisting of soda lime glass (SLG), low iron white glass, and alkali-free glass.

17. The thin film solar cell according to claim 16, wherein the photoconductive layer is made of a material selected from the group consisting of amorphous silicon (a-Si), polysilicon, and microcrystalline silicon.

18. The thin film solar cell according to claim 17, wherein the photoconductive layer is configured with a p-i-n type composite structure.

19. The thin film solar cell according to claim 17, wherein the back electrode layer is made of a material selected from the group consisting of silver (Ag), aluminum (Al), chromium (Cr), titanium (Ti), nickel (Ni), and gold (Au).

20. The thin film solar cell according to claim 17, wherein the photoconductive layer is formed by a plasma enhanced chemical vapor deposition (PECVD) process.

21. The thin film solar cell according to claim 1, wherein the front electrode layer is made of a transparent conductive oxide selected from the group consisting of tin oxide (SnO₂), indium tin oxide (ITO), zinc oxide (ZnO), aluminum zinc oxide (AZO), gallium zinc oxide (GZO), and indium zinc oxide (IZO).

22. The thin film solar cell according to claim 1, wherein the front electrode layer is formed by a process selected from the group consisting of a sputtering process, an atmospheric pressure chemical vapor deposition (APCVD) process, and a low pressure chemical vapor deposition (LPCVD) process.

23. The thin film solar cell according to claim 1, wherein the front electrode layer is configured with a single layer structure or a multilayer structure.

24. The thin film solar cell according to claim 1, wherein the back electrode layer is configured with a single layer structure or a multilayer structure.

25. The thin film solar cell according to claim 1, wherein the back electrode layer is formed by a process selected from the group consisting of a sputtering process and a physical vapor deposition (PVD) process.

26. A thin film solar cell having a photo-luminescent medium coated therein, comprising:
a transparent layer, provided at a light incident surface of the thin film solar cell;
a photo-luminescent medium, stacked on the transparent layer;
a front electrode layer, stacked on the photo-luminescent medium;
a photoconductive layer, stacked on the front electrode layer; and
a back electrode layer, stacked on the photoconductive layer,
wherein the photo-luminescent medium layer is adapted for absorbing a part of an incident light having a relative short wavelength and then being excited to emit a light having a relative long wavelength, thus improving a higher spectra response (HSR) region of the photoconductive layer, and achieving an improved photoelectric conversion efficiency.

27. The thin film solar cell according to claim 26, wherein the photo-luminescent medium is provided at an inner surface of the transparent layer or a surface of the front electrode layer.

28. The thin film solar cell according to claim 26, wherein the photo-luminescent medium is (Ba,Sr)₂SiO₄:Eu for converting a blue light into a green light.

29. The thin film solar cell according to claim 26, wherein the photo-luminescent medium is selected from the group consisting of Y₃Al₅O₁₂:Ce, (Ba,Sr)₂SiO₄:Eu and Li-α-SiAlON:Eu, for converting a blue or a green light into a yellow light.

30. The thin film solar cell according to claim 26, wherein the photo-luminescent medium is selected from the group consisting of Ca-α-SiAlON:Eu and (Sr, Ca)AlSiN₃:Eu for converting a blue light or a green light into an orange light.

31. The thin film solar cell according to claim 26, wherein the photo-luminescent medium is selected from the group consisting of CaS:Eu, SrS:Eu, and CaAlSiN₃:Eu for converting a blue light or a green light into a red light.

32. The thin film solar cell according to claim 26, wherein the photo-luminescent medium is an inorganic compound comprising a host and an activator.

33. The thin film solar cell according to claim 32, wherein the host is selected from the group consisting of metal oxide, sulfide, nitride, and oxynitride.

34. The thin film solar cell according to claim 32, wherein the activator is selected from the group consisting of cerium (Ce), terbium (Tb), europium (Eu), manganese (Mn), and praseodymium (Pr).

35. The thin film solar cell according to claim 26, wherein a substrate further stacked under the back electrode layer.

36. The thin film solar cell according to claim 35, wherein the transparent layer is a cover glass.

37. The thin film solar cell according to claim 35, wherein the substrate is made of a transparent glass, a thermally stable polymer material, or a metal material.

38. The thin film solar cell according to claim 35, wherein the photoconductive layer is made of a material selected from the group consisting of copper indium selenide (CIS) and copper indium gallium selenide (CIGS).

39. The thin film solar cell according to claim 38, wherein the photoconductive layer is further grown with a cadmium sulfide (CdS) layer thereon, thus obtaining a photoconductive layer having a p-n type CIGS/CdS or CIGS/CdS composite structure.

40. The thin film solar cell according to claim 38, wherein the back electrode layer is made of molybdenum (Mo).

41. The thin film solar cell according to claim 38, wherein the photoconductive layer is formed by a physical vapor deposition (PVD) process comprising a sputtering process or an evaporation process.

42. The thin film solar cell according to claim 26, wherein the transparent layer is a transparent substrate made of a material selected from the group consisting of soda lime glass (SLG), low iron white glass, and alkali-free glass.

43. The thin film solar cell according to claim 42, wherein the photoconductive layer is made of a material selected from the group consisting of amorphous silicon (a-Si), polysilicon, and microcrystalline silicon.

44. The thin film solar cell according to claim 43, wherein the photoconductive layer is configured with a p-i-n type composite structure.

45. The thin film solar cell according to claim 43, wherein the back electrode layer is made of a material selected from the group consisting of silver (Ag), aluminum (Al), chromium (Cr), titanium (Ti), nickel (Ni), and gold (Au).

46. The thin film solar cell according to claim 43, wherein the photoconductive layer is formed by a plasma enhanced chemical vapor deposition (PECVD) process.

47. The thin film solar cell according to claim 26, wherein the front electrode layer is made of a transparent conductive oxide selected from the group consisting of tin oxide (SnO₂), indium tin oxide (ITO), zinc oxide (ZnO), aluminum zinc oxide (AZO), gallium zinc oxide (GZO), and indium zinc oxide (IZO).

48. The thin film solar cell according to claim 26, wherein the front electrode layer is formed by a process selected from the group consisting of a sputtering process, an atmospheric pressure chemical vapor deposition (APCVD) process, and a low pressure chemical vapor deposition (LPCVD) process.

49. The thin film solar cell according to claim 26, wherein the front electrode layer is configured with a single layer structure or a multilayer structure.

50. The thin film solar cell according to claim 26, wherein the back electrode layer is configured with a single layer structure or a multilayer structure.

51. The thin film solar cell according to claim 26, wherein the back electrode layer is formed by a process selected from the group consisting of a sputtering process and a physical vapor deposition (PVD) process.

52. A method for fabricating a thin film solar cell having a photo-luminescent medium coated therein, comprising the steps of:
(1) providing a photo-luminescent medium, wherein the photo-luminescent medium is a single component or a mixture;
(2) providing an adhesive, selected from the group consisting of silica gel, silicone, epoxy, and ethylene vinyl acetate (EVA);
(3) mixing the photo-luminescent medium with the adhesive, to uniformly disperse the photo-luminescent medium into a matrix of the adhesive, for obtaining a mixture of the photo-luminescent medium and the adhesive;
(4) conducting a degassing process to the mixture of the photo-luminescent medium and the adhesive; and
(5) loading the degassed mixture into a coater for coating a photo-luminescent medium layer onto the thin film solar cell, and then curing the coated photo-luminescent medium layer.

53. The method according to claim 52, wherein a method of coating the photo-luminescent medium layer onto the thin film solar is selected from screen printing, roll coating, slit coating, gravure printing, and slot die coating.

54. The method according to claim 52, wherein a thickness of the photo-luminescent medium layer coated on the thin film solar cell ranges from 10 μm to 200 μm.

55. The method according to claim 52, wherein a thickness of the photo-luminescent medium coated on the thin film solar cell ranges from 50 μm to 100 μm.

56. The method according to claim 52, wherein a content percentage of the photo-luminescent medium in the mixture ranges from 0.005% to 20%.

57. The method according to claim 52, wherein a content percentage of the photo-luminescent medium in the mixture ranges from 0.05% to 1%.
